(19) United States
(12) Patent Application Publication
(10) Pub. No.: US 2024/0170738 A1
(43) Pub. Date: May 23, 2024

(54) THREE DIMENSIONAL LITHIUM ANODE WITH A CAPPING LAYER

(71) Applicant: Oerlikon Surface Solutions AG, Pfäffikon, Pfäffikon (CH)

(72) Inventor: Siva Phani Kumar YALAMANCHILI, Sargans (CH)

(21) Appl. No.: 18/552,110

(22) PCT Filed: Mar. 24, 2022
(86) PCT No.: PCT/EP2022/057786

§ 371 Date: Sep. 22, 2023

(30) Foreign Application Priority Data
Mar. 24, 2021 (DE) 10 2021 001 522.3

(51) Int. Cl. H01M 10/42; B60K 1/04; B60L 50/64; H01M 4/02; H01M 4/04; H01M 4/134; H01M 4/1395; H01M 4/38; H01M 4/66

(52) U.S. Cl. CPC H01M 10/4235; B60K 1/04; B60L 50/64; H01M 4/0404; H01M 4/0423; H01M 4/134; H01M 4/1395; H01M 4/382; H01M 4/661; H01M 2004/021; H01M 2004/027; H01M 2220/20

(57) ABSTRACT

A battery half-cell comprising a copper foil, a lithium anode layer deposited on a surface of the copper foil and a capping layer, preferably a conformal capping layer, deposited on the lithium anode layer. The lithium anode layer comprises vertical structures such as columnar structures and/or grid structures.

### TECHNICAL FIELD

The present invention relates to a three dimensional lithium anode as well as the production of such a three dimensional lithium anode comprising a capping layer.

### BACKGROUND OF THE INVENTION

Lithium is one of the most important elements for nowadays batteries. The so called Li⁺ ion batteries build on the tendency of lithium to give away its outer electron. Such batteries typically comprise a lithium layered oxide cathode and a graphitic anode which are separated by a liquid or solid state electrolyte comprising as well a separator.

If the battery is discharged, all of the Li atoms reside in the grid of the cathode. In order to charge the battery, a voltage is applied, the positive pole is connected with the cathode and the negative pole is connected with the anode. As consequence, electrons are drawn out of the cathode and the Li atoms get ionized to Li⁺ ions. Due to the electric field established between cathode (+) and anode (−) the Li⁺ ions start being attracted by the anode and are flowing/diffusing through the electrolyte into the graphite of the anode where they absorb an electron and stay until further. Once all Li⁺ ions entered the anode, took an electron so that there are no ions any more, the battery is fully charged.

When disconnected from the charging source, the metal of the cathode is missing the electrons it shared before with the Li-atoms. Therefore the cathode remains a positive pole whereas the anode is at negative potential as compared to the cathode.

However, if now a consumer (consuming electrical current) connects anode and cathode, electrons are attracted via the connections of the consumer to the cathode. This causes the Li-atoms again to give away their outer electron. These electrons flow from the graphite into the connection cables of the anode and via the consumer into the connection cables of the cathode back to the positively charged metallic oxide cathode. As more and more Li⁺ ions are concentrated in the anode (who lost their outer electron), they start diffusion via the electrolyte (passing the separator) into the metallic oxide cathode.

This diffusion is supported by the positive charge of the Li⁺ ions as they (being charged in the same manner) try to be separated as much as possible. The battery is fully discharged when there is no potential difference any more between cathode and anode.

There is one problem with currently available anodes based on graphite: Their capacity to absorb Li atoms is very limited. This means in order to increase the (electrical) capacity of a battery, more graphite has to be provided and the size and weight of the battery increases. Especially in connection with electric vehicles, the weight and size of the battery is the limiting factor. This is why a technical solution for a battery is judged in terms of mAh/g.

Newer approaches combine graphite with silicon which show higher capacity as compared to graphite alone.

Lithium metal itself is a very promising candidate for anode material because of its high theoretical capacity of 3860 mAh/g and the low anode potential.

Unfortunately lithium metal has at least the following four major disadvantages:
1. it is highly reactive, which means that after short time exposure to air and/or water a lithium surface is degenerated
2. in order realize an efficient anode, a very thin lithium layer (<20 μm) needs to be realized
3. lithium tends to form dendritic growth which among other problems results in instabilities of the layer
4. large volume changes result in volumetric instabilities and therefore limited life cycles

The first problem may be addressed with the help of a capping layer. This can be formed by graphite, lithium lanthanum zirconium oxide (LLZO), lithium phosphorous oxy-nitride (LIPON) or a mixture thereof. Lithium ions then diffuse through this layer and add to the interface without showing dendritic growth.

Unfortunately the problem of the volume change is still present.

### SUMMARY OF THE INVENTION

According to one aspect of the present invention Li₂O is used as target material to perform arc discharge and/or ebeam (electron beam) evaporation.

Introducing a reactive gas X into the reaction chamber and with the help of the high energy impact of the arc discharge and/or ebeam evaporation, the Li₂O is insitu reduced to Li₂ and XO. If X is for example hydrogen, the reaction can be described as Li₂O+H₂→Li₂+H₂O. It is as well possible to use CH₄ as reactive Gas. Another possibility would be to integrate Carbon in the target. In doing so, the target can be made electrically conductive which facilitates the arc deposition process. Carbon then reacts with the oxygen to CO and/or CO₂. Carbon particles which do not react have a chance to be integrated into the capping layer, thereby forming an integrated part of such layer.

Possible reactions, which can be used, are for example:

Hydrogen: H₂+Li₂O→2Li+H₂O

Carbon: C+2Li₂O→4Li+CO₂

C+Li₂O→2Li+CO

Carbonmonoxid: CO+Li₂O→2Li+CO₂

Methane: CH₄+4Li₂O→+4Li+2H₂O+CO₂

Calculations of the Delta in free Energy (ΔG) of these reactions show in a temperature range from 0° K to 3000° K that only in the case if Carbon is provided as gas the Delta is negative between 1300° K and 2500° K. For the rest of the reactions ΔG is positive up to 3000° C. Therefore under these conditions, the said reactions will not happen.

In contrast however, if Li₂O⁺ ions are used, the Delta in free Energy is dramatically decreased and latest at a temperature of 1300° K all Deltas are negative. In this context it is important to know that the arc deposition process is typically a process producing a high ionization degree of evaporated particles with an energy of ˜10-20 eV.

According to another aspect of the present invention, a lithium layer with vertical structures and preferred a columnar lithium layer which forms the anode layer is build up on a substrate such as for example a Cu foil. The columnar structure may be realized with arc deposition technology tuning the ad-atom energy for example by tuning the substrate temperature, pressure within the coating chamber, ionization degree and/or the substrate bias. A vertical structure is a structure that rises—at least approximately or essentially—perpendicularly from a large main surface of the copper foil that forms the deposition base.

According to another aspect of the present invention the columnar Li anode layer is covered with a conformal capping layer using atomic layer deposition (ALD) and/or plasma enhanced chemical vapor deposition (PECVD). In some cases it is possible as well to build the capping layer by magnetron sputtering. The conformal capping layer can for example be a carbon layer and/or a layer of amorphous/crystalline Li₇La₃Zr₂O₁₂ (LLZO) and/or a layer of lithium phosphorous oxynitride (LIPON) and/or a layer of lithium boron oxynitride (LIBON). In the case of LIPON and/or LIBON these materials not only protect the anode layer but as well constitute solid electrolytes which in addition have the filter function in terms of only letting pass the Li⁺ ions, which makes an additional separator unnecessary. Furthermore, a gradient in amorphous to crystalline structure of the capping layer can be readily achieved by tuning the process parameters such as target current etc. A fully amorphous is beneficial at the interface close to the metallic lithium anode to suppress the undesirable dendritic growth.

Without wanting to make an exclusionary definition for the time being but for expressing what is preferred, it is said that:

In any case all such layers are “conformal” where layer thickness deviations of less than 5% and ideally of less than 50 nm are to be measured (fully or essentially) everywhere, preferably measured in electron microscopy followed by a focused ion beam cut orthogonal to the sample surface.

### BRIEF DESCRIPTION OF THE DRAWINGS

The invention will be now described with an example and with the help of the figures.

FIG. 1 shows the calculated Delta in free energy for reactions leading to a reduction of Li₂O.

FIG. 2 schematically shows the production setup of the 3D lithium anode according to the present invention.

FIG. 3 shows the columnar growth of a thin film realized with cathodic arc deposition by choosing the adequate coating parameters. A desired feature is to create a high surface area by reducing the column width, typically less than 100 nm.

### DETAILED DESCRIPTION OF THE INVENTION

Starting point is a mixture of Li₂O powder and graphite powder. In the present example 70 at % LiO2 is mixed with 30 at % graphite. After mixing, the powder is pressed and sintered to a solid state target to be used as cathode in a cathodic arc deposition process. This target is introduced into an arc deposition chamber. As Li₂O is an electrical insulator, cathodic arc deposition would be very difficult with pure Li₂O. With the graphite particles forming an electrically conducting matrix, the cathodic arc deposition process can be performed. In the example, copper foils are the substrates to be coated. They are as well introduced into the coating chamber and placed in such a way that the copper surfaces to be coated at least at a certain time period during the coating process face the target surface.

The coating chamber is then evacuated and an arc is initiated on the surface of the target, in the area of the spot locally extracting electrons out of the surface thereby heating the location of the target surface in such a manner, that Li₂O particles are evaporated and ionized. Carbon particles are as well evaporated and due to the high energy level of the plasma within the arc the inventor believes that lithium and oxygen are separated. The oxygen later on reacts with the carbon atoms and form CO and/or CO₂ gases, whereas the lithium ions are deposited onto the surfaces of the copper foils. In order to fully avoid recombination of lithium and oxygen back to Li₂O, hydrogen gas is introduced into the coating chamber which combines with the free oxygen to water during the coating process.

In order to additionally accelerate the Li⁺ ions to the surface to be coated, it is possible to apply a negative voltage (bias) to the substrates. Minus hundred volts (−100V) would be a good value to be used, however the amount of bias can be used to adjust the morphology of the coating, mainly because this influences the substrate temperature (the higher the kinetic energy of the Li⁺ ions, the more heated the substrate surface). As pointed out above, morphology is important as a columnar structure needs to be realized in order to form the (three-dimensional) columnar Li-anode layer. Other possibilities to influence the morphology is the pressure in the coating chamber and the degree of ionization. A higher degree of ionization can be realized by pulsing the power used for keeping the arc burning. Pulsing the power in addition helps to reduce the so called droplet forming. However, in order to completely eliminate droplet deposition on the surface, a so called filtered arc deposition might be necessary. FIG. 3 shows a thin film deposited with cathodic arc resulting in a columnar structure as preferred in the context of the present invention.

FIG. 3 shows quite clearly what optionally distinguishes a columnar structure:

The substrate which carries the deposition is a (copper) foil. It is visible in the lower most horizontal area of FIG. 3.

The (in most cases fully three dimensional) columnar structure consists of a multitude of columnar structural elements packed directly next to each other. Not always, but as a rule, which can be clearly seen in FIG. 3, they are predominantly or even essentially formed in such a way that they have a longitudinal axis in the vertical direction. Preferably, the columnar structural elements have predominantly or even essentially a cross-section perpendicular to their longitudinal axis, the largest dimension of which is smaller by at least a factor of 4, preferably by at least a factor of 6, than the maximum dimension of the respective columnar element in the direction of said longitudinal axis. Ideally, the free ends of the columnar structural elements exhibit a needle-like taper, for example of approximately pyramidal or conical type. Preferably, there is no or no substantial free space between immediately adjacent columnar structural elements, with the exception of the areas of needle-like tapering. Preferred, the said columnar structural elements are randomly distributed. It is preferred if the said columnar structural elements are nano-sized, ideally with a diameter of less than 250 nm, see FIG. 3.

On the other hand it is well possible that droplets of Li₂O particles integrated into the Li anode layer might even improve the performance of the anode as these contribute to the structuring of the anode layer.

The columnar Li-anode layer is built up to a thickness of 15 μm.

As the last step a carbon layer is coated on the columnar Li-anode layer. This is done by plasma enhanced chemical vapor deposition. For this methane gas is introduced into the coating chamber and a plasma is established which dissociates the CH₄ into carbon and hydrogen. Carbon is then condensed on the surfaces present in the chamber, including but not limited to the substrates coated with the columnar Li-anode layer. The carbon layer is deposited up to a thickness of 50 nm. The coating process is conducted in such a way that only (about or essentially) 25% of the carbon bondings are sp3 bonds, giving the carbon layer its stability. Moreover (about or essentially) 75% of the bondings are sp2 bonds. Therefore, the carbon layer has mainly graphitic characteristics.

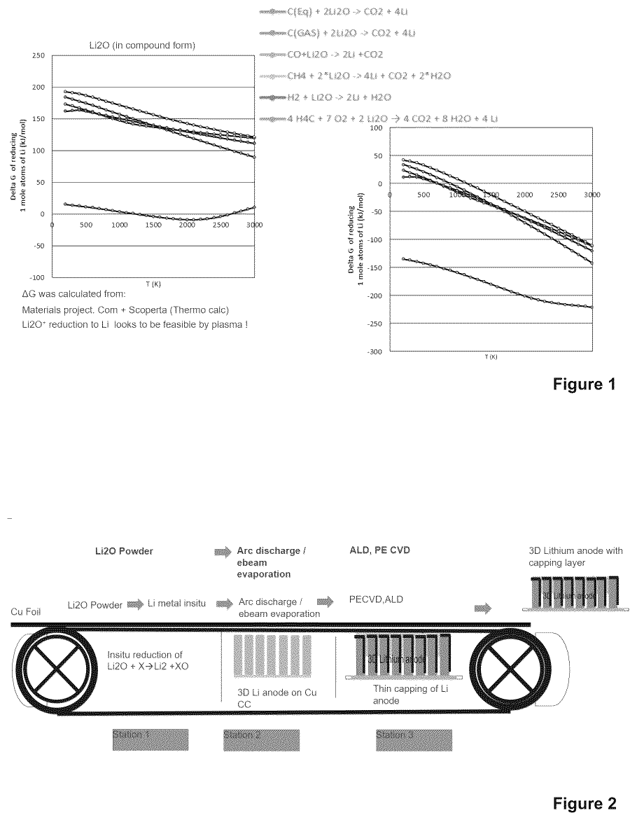

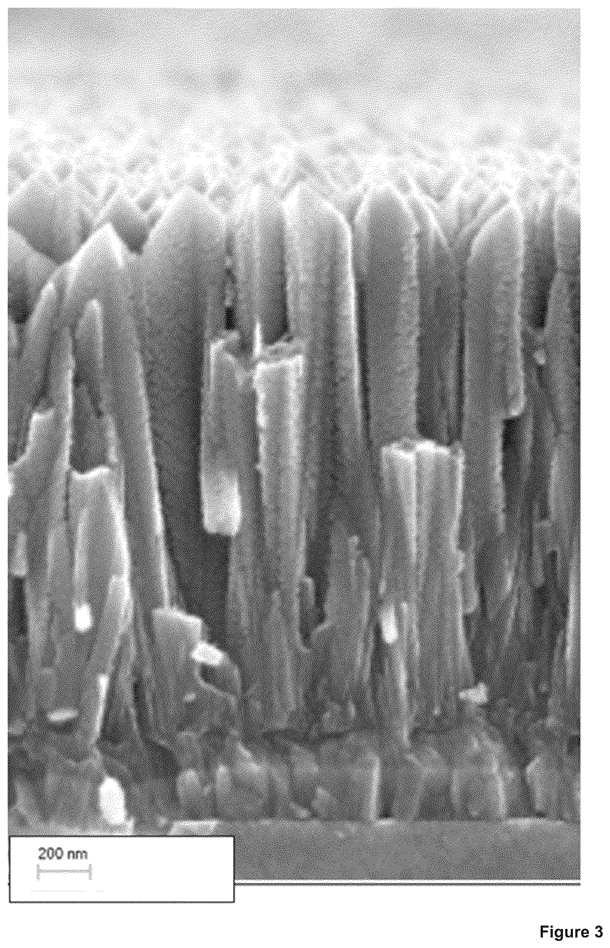

FIG. 2 offers an overview over a preferred embodiment of the inventive procedure. FIG. 2 shows the realization of the proposed structures in an inline machine.

From the left the Cu substrate is fed, mostly in the shape of a foil.

In station 1, the Li₂O powder is in situ reduced to Lithium.

In station 2, the reduced Lithium is vapor deposited by either arc discharge/ebeam (electron beam) evaporation etc. in the form of three dimensional vertical structures with a size less than preferably 100 nm.

In station 3, a thin conformal coating is provided on the said vertical structures to enhance functionality of the lithium anode.

As result, the arrangement shown by FIG. 2 generates a functional 3D structured lithium anode protected with the capping layer from the Li₂O raw material, as preferred directly.

In order to improve the adhesion of the Li anode layer to the copper substrate it is possible to first deposit an adhesion layer before Li is deposited. According to a preferred embodiment of the present invention, the deposition starts with copper and the Li deposition is ramped up while copper deposition is ramped down to zero. This results in a gradient layer which guarantees excellent adhesion of Li to copper as well as excellent electrical contact between the copper substrate and the Li anode layer.

According to another preferred embodiment, the deposition target comprises copper rather than carbon. On the one hand, this improves the coating condition as the copper is electrically conducting and allows for a smooth cathodic arc deposition process. On the other hand, the copper in the Li anode layer improves the adhesion to the copper substrates.

In the present description is disclosed a battery half-cell comprising a copper foil, a lithium anode layer deposited on a surface of the copper foil and a capping layer, preferably a conformal capping layer, deposited on the lithium anode layer. The lithium anode layer comprises vertical structures such as columnar structures and/or grid structures.

The expression “Grid structures” refers to surface structuring which is not reached by the deposition process, but which is formed after deposition of the Li. Methods in order to realize such grids could be for example interference procedures with photoresist and etching. Typical gird periods would be 100 nm to several microns, for example up to 3 or only 2 microns. Typical duty cycles could be 20:80 to 80:20.

The lithium anode layer may have a thickness equal to or less than 20 μm.

The capping layer may comprise a material out of the group formed by carbon, LLZO, LIPON and LIBON or a combination thereof.

The capping layer may have a thickness not thinner than 20 nm and not thicker than 120 nm and preferably has a thickness of 50 nm.

A method to manufacture a battery half-cell was disclosed with a Li anode layer, comprising the steps of:
coating a surface of a metal substrate, preferably a surface of a copper foil by performing PVD, preferably performing cathodic arc deposition with a target as material source which comprises Li₂O as material, thereby forming a Li anode layer, wherein the Li anode layer is deposited and eventually post treated in such a way that it comprises vertical structures such as columnar structure and/or grid structures
depositing a capping layer onto the Li anode layer by at least one of atomic layer deposition, plasma enhanced chemical vapor deposition, magnetron sputtering and/or cathodic arc deposition.

Thereby in any case a post treatment relates either to removing of droplets (for example by polishing) or, in order to realize grid structure, relates to surface structuring e.g. based on interference and etching techniques as described above.

The target used in the method may as well comprise carbon and/or copper.

During arc deposition from the Li₂O comprising target a reacting gas preferably hydrogen and/or CO and/or methane may be introduced in order to support the reduction of Li₂O* to metallic lithium.

1. A battery half-cell comprising:
a copper foil,
a lithium anode layer deposited on a surface of the copper foil, and
a capping layer deposited on the lithium anode layer, wherein the lithium anode layer comprises vertical structures.

2. The battery half-cell according to claim 1, wherein the lithium anode layer has a thickness equal to or less than 20 μm.

3. The battery half-cell according to claim 1, wherein the capping layer comprises a material selected from the group consisting of carbon, LLZO, LIPON, LIBON, and combinations thereof.

4. The battery half-cell according to claim 1, wherein the capping layer has a thickness not thinner than 20 nm and not thicker than 120 nm.

5. A method to manufacture a battery half-cell with a Li anode layer, comprising the steps of:
coating a surface of a metal substrate by performing PVD, thereby forming a Li anode layer, wherein the Li anode layer is deposited and eventually post treated in such a way that the Li anode laver comprises vertical structures; and
depositing a capping layer onto the Li anode layer by at least one of the group consisting of atomic layer deposition, plasma enhanced chemical vapor deposition, magnetron sputtering and cathodic arc deposition.

6. The method according to claim 13, wherein the target further comprises carbon and/or copper.

7. The method according to claim 6 wherein during arc deposition from the Li₂O comprising target a reacting gas introduced in order to support a reduction of Li₂O* to metallic lithium.

8. A battery comprising a cathode, an electrolyte and an anode, wherein the anode is an anode according to claim 1.

9. A vehicle which is moved by an electromotor, and power supply for driving the electromotor comprises at least one battery according to claim 8.

10. The battery half-cell according to claim 1, wherein the capping layer is a conformal capping layer.

11. The battery half-cell according to claim 1, wherein the vertical structures comprise columnar structures and/or grid structures.

12. The method according to claim 5, wherein the metal substrate is a copper foil.

13. The method according to claim 5, comprising coating the surface of the metal substrate by performing cathodic arc deposition with a target as material source which comprises Li₂O as material.

14. The method according to claim 5, wherein the vertical structures comprise columnar structures and/or grid structures.

15. The method according to claim 7, wherein the reaction gas is selected from the group consisting of hydrogen, CO, methane, and combinations thereof.
